(19) United States
(12) Patent Application Publication
(10) Pub. No.: US 2025/0246402 A1
(43) Pub. Date: Jul. 31, 2025

(54) MULTIPLE CHARGED PARTICLE BEAM WRITING METHOD, MULTIPLE CHARGED PARTICLE BEAM WRITING APPARATUS, AND NON-TRANSITORY COMPUTER-READABLE STORAGE MEDIUM STORING PROGRAM THEREIN

(71) Applicant: NuFlare Technology, Inc., Yokohama-shi (JP)

(72) Inventors: Yasuo KATO, Yokohama-shi (JP); Yuji FUJIWARA, Yokohama-shi (JP)

(73) Assignee: NuFlare Technology, Inc., Yokohama-shi (JP)

(21) Appl. No.: 19/008,777

(22) Filed: Jan. 3, 2025

(30) Foreign Application Priority Data
Jan. 31, 2024 (JP) 2024-013619

(51) Int. Cl. H01J 37/317; H01J 37/304

(52) U.S. Cl. CPC H01J 37/3177; H01J 37/3045; H01J 2237/24535; H01J 2237/30461; H01J 2237/31776

(57) ABSTRACT

According to one aspect of the present invention, a multiple charged particle beam writing method includes: setting one of a plurality of weighting coefficients, for each beam of multiple charged particle beams according to arrangement positions of the multiple charged particle beams; and correcting, in a case where multiple writing is performed on a same position of a target object as a writing target with a plurality of beams at different arrangement positions, two or more kinds of weighting coefficients being set for the plurality of beams, among the multiple charged particle beams, a dose of a beam concerned obtained in advance, using the two or more kinds of weighting coefficients of the plurality of beams with which writing is performed on the position, for each beam of the plurality of beams with which the position is irradiated.

### CROSS-REFERENCE TO RELATED APPLICATION

This application is based upon and claims the benefit of priority from prior Japanese Patent Application No. 2024-013619 filed on Jan. 31, 2024 in Japan, the entire contents of which are incorporated herein by reference.

### BACKGROUND OF THE INVENTION

### Field of the Invention

One aspect of the present invention relates to a multiple charged particle beam writing method, a multiple charged particle beam writing apparatus, and a program, and relates to, for example, a method of correcting a beam irradiation time in multiple writing using multiple beams in which current density distribution occurs.

### Related Art

Lithography technology leading progress of miniaturization of semiconductor devices is only a process of generating a pattern in semiconductor manufacturing processes, and is extremely important. In recent years, with high integration of LSI, a circuit line width required for a semiconductor device has been miniaturized year by year. Here, an electron beam writing technique has essentially excellent resolution, and writing is performed on a wafer or the like using an electron beam.

For example, there is a writing apparatus using multiple beams. As compared with a case where writing is performed with one electron beam, a large number of beams can be emitted at a time by using multiple beams, so that the throughput can be greatly improved. In such a multi-beam writing apparatus, for example, an electron beam emitted from an electron emission source is made to pass through a mask having a plurality of holes to form multiple beams, each beam is controlled for blanking, and each beam that is not shielded is reduced by an optical system and deflected by a deflector so that a desired position on a target object is irradiated therewith.

Here, in the multiple beams used for multiple beam writing, the current densities of the beams are not uniform, and a current density distribution occurs. Therefore, when writing is performed without correction, a required dose cannot be obtained, and the writing accuracy is deteriorated. In order to cope with such an issue, conventionally, when a target object is irradiated with beams, a method of correcting a designed dose for each beam using, as a correction coefficient, a ratio obtained by dividing an ideal current density by a current density of the beam has been used. In such a case, correction is performed for each shot, so that in a case where there is a beam having a singular current density, there may be a case where a singular beam irradiation time is required as compared with beam irradiation times for other shots. In the multi-beam writing, the shot cycle is set to match with the maximum value of the beam irradiation times, so that the entire writing time becomes long and the throughput deteriorates if there is a shot with a singular beam irradiation time.

Therefore, in a case where multiple writing is performed on a target object, a method has been devised in which current densities of beams used in each pass are averaged, and a ratio obtained by dividing an ideal current density by the averaged current density is used as a correction coefficient to correct a designed dose of each pass (see JP 2023-056384 A). As a result, the singular current density can be averaged, so that the singular beam irradiation time can be suppressed.

In such a case, since the same correction coefficient is used for a plurality of beams with which the same position is irradiated, the beam irradiation times in the passes may be the same. As a result, quantization errors are stacked in the same manner, and there arises an issue that an error occurs in the actual dose.

### BRIEF SUMMARY OF THE INVENTION

According to one aspect of the present invention, a multiple charged particle beam writing method includes:
setting one of a plurality of weighting coefficients, for each beam of multiple charged particle beams according to arrangement positions of the multiple charged particle beams;
correcting, in a case where multiple writing is performed on a same position of a target object as a writing target with a plurality of beams at different arrangement positions, two or more kinds of weighting coefficients being set for the plurality of beams, among the multiple charged particle beams, a dose of a beam concerned obtained in advance, using the two or more kinds of weighting coefficients of the plurality of beams with which writing is performed on the position, for each beam of the plurality of beams with which the position is irradiated; and
writing a pattern on the target object using the multiple charged particle beams by performing multiple writing on a position of the target object with the plurality of beams with respective corrected doses of the plurality of beams for each position of the target object.

According to another aspect of the present invention, a multiple charged particle beam writing apparatus includes:
a setting circuit configured to set one of a plurality of weighting coefficients, for each beam of multiple charged particle beams according to arrangement positions of the multiple charged particle beams;
a correcting circuit configured to correct, in a case where multiple writing is performed on a same position of a target object as a writing target with a plurality of beams at different arrangement positions, two or more kinds of weighting coefficients being set for the plurality of beams, among the multiple charged particle beams, a dose of a beam concerned obtained in advance, using the two or more kinds of weighting coefficients of the plurality of beams with which writing is performed on the position for each beam of the plurality of beams with which the position is irradiated; and
a writing mechanism configured to write a pattern on the target object using the multiple charged particle beams by performing multiple writing on a position of the target object with the plurality of beams with respective corrected doses of the plurality of beams for each position of the target object.

According to yet another aspect of the present invention, a non-transitory computer-readable storage medium storing a program for causing a computer to execute processing, includes:
setting one of a plurality of weighting coefficients, for each beam of multiple charged particle beams according to arrangement positions of the multiple charged particle beams;
storing the weighting coefficient set for each beam in a storage device; and
reading the weighting coefficient from the storage device, correcting, in a case where multiple writing is performed on a same position of a target object as a writing target with a plurality of beams at different arrangement positions, two or more kinds of weighting coefficients being set for the plurality of beams, among the multiple charged particle beams, a dose of a beam concerned obtained in advance, using the two or more kinds of weighting coefficients of the plurality of beams with which writing is performed on the position, for each beam of the plurality of beams with which the position is irradiated, and outputting a corrected dose.

### BRIEF DESCRIPTION OF THE DRAWINGS

FIG. 1 is a conceptual diagram illustrating a configuration of a writing apparatus according to a first embodiment;

FIG. 2 is a conceptual diagram illustrating a configuration of a shaping aperture array substrate according to the first embodiment;

FIG. 3 is a cross-sectional view illustrating a configuration of a blanking aperture array mechanism according to the first embodiment;

FIG. 4 is a conceptual diagram for describing an example of a writing operation in the first embodiment;

FIG. 5 is a diagram illustrating an example of an irradiation region of multiple beams and a writing target pixel in the first embodiment;

FIG. 6 is a diagram for describing an example of a multiple beam writing operation in the first embodiment;

FIG. 7 is a diagram illustrating an example of a current density distribution in the first embodiment;

FIG. 8 is a diagram for describing a method of correcting a deviation in beam irradiation time due to a difference in current density in a first comparative example of the first embodiment;

FIG. 9 is a diagram for describing a method of correcting a deviation in beam irradiation time due to a difference in current density in a second comparative example of the first embodiment;

FIG. 10 is a diagram for describing an example of multiple writing of multiplicity 2 in the first embodiment;

FIG. 11 is an example of a flowchart illustrating main steps of a writing method according to the first embodiment;

FIG. 12 is a diagram for describing an example of multiple writing of multiplicity 4 in the first embodiment;

FIG. 13 is a diagram illustrating an example of group regions of weighting coefficients in the first embodiment;

FIG. 14 is a diagram illustrating an example of a block configuration in a beam array according to the first embodiment;

FIG. 15 is a diagram illustrating another example of group regions of the weighting coefficients in the first embodiment;

FIG. 16 is a diagram for describing how to perform multiple writing according to a modification of the first embodiment;

FIG. 17 is a diagram illustrating an example of a correction coefficient distribution and quantization errors in the first comparative example of the first embodiment;

FIG. 18 is a diagram illustrating an example of a correction coefficient distribution and quantization errors in the second comparative example of the first embodiment;

FIG. 19 is a diagram illustrating an example of a correction coefficient distribution and quantization errors in the first embodiment;

FIG. 20 is a diagram for describing a first modification of weighting coefficients in the first embodiment; and

FIG. 21 is a diagram for describing a second modification of weighting coefficients in the first embodiment.

### DETAILED DESCRIPTION OF THE INVENTION

Hereinafter, in an embodiment, a writing method and a writing apparatus capable of reducing a quantization error while suppressing a decrease in throughput regardless of the presence or absence of a beam having a singular current density when multiple writing is performed on a target object using multiple beams.

Hereinafter, in the embodiment, a configuration using an electron beam as an example of a charged particle beam will be described. However, the charged particle beam is not limited to the electron beam, and may be a beam using charged particles such as an ion beam.

### First Embodiment

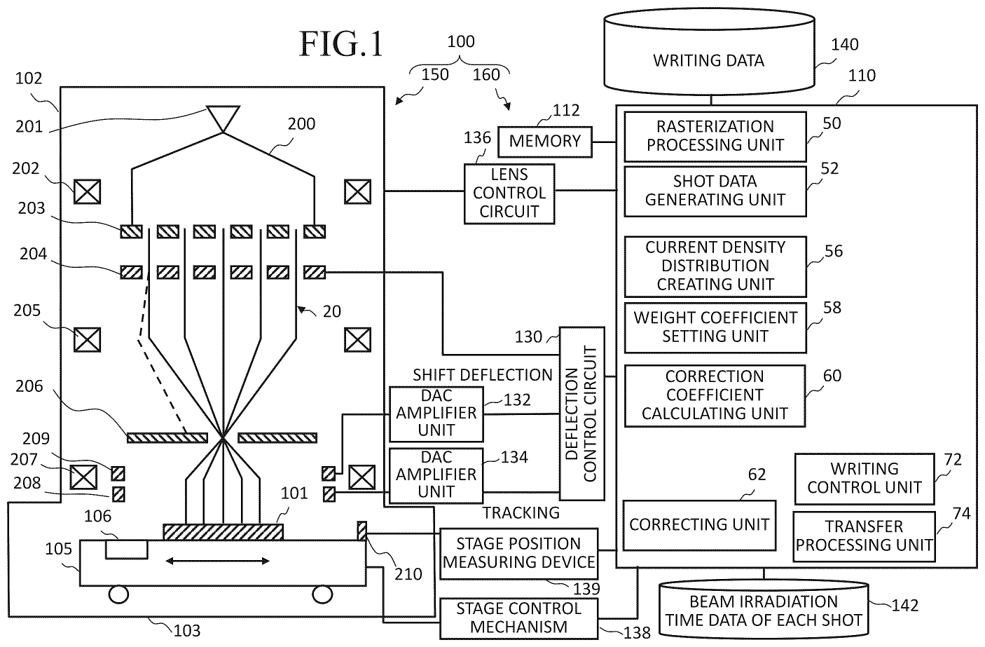

FIG. 1 is a conceptual diagram illustrating a configuration of a writing apparatus according to a first embodiment. In FIG. 1, a writing apparatus 100 includes a writing mechanism 150 and a control system circuit 160. The writing apparatus 100 is an example of a multiple charged particle beam writing apparatus and an example of a multiple charged particle beam exposure apparatus. The writing mechanism 150 includes an electron optical column 102 (electron beam column) and a writing chamber 103. In the electron optical column 102, an electron emission source 201, an illumination lens 202, a shaping aperture array substrate 203, a blanking aperture array mechanism 204, a reduction lens 205, a limiting aperture substrate 206, an objective lens 207, a main deflector 208, and a sub-deflector 209 are disposed.

In the writing chamber 103, an XY stage 105 is disposed. On the XY stage 105, a target object 101 such as a mask to be a substrate on which a pattern is written at the time of writing (at the time of exposure) is disposed. The target object 101 includes an exposure mask for manufacturing a semiconductor device, a semiconductor substrate (silicon wafer) on which a semiconductor device is manufactured, or the like. The target object 101 includes mask blanks on which a resist is applied and on which no pattern is written. On the XY stage 105, a mirror 210 for position measurement of the XY stage 105 is further disposed.

A Faraday cup 106 is disposed on the XY stage 105.

The control system circuit 160 includes a control computer 110, a memory 112, a deflection control circuit 130, a digital/analog conversion (DAC) amplifier units 132 and 134, a lens control circuit 136, a stage control mechanism 138, a stage position measuring device 139, and storage devices 140 and 142 such as a magnetic disk drive. The control computer 110, the memory 112, the deflection control circuit 130, the lens control circuit 136, the stage control mechanism 138, the stage position measuring device 139, and the storage devices 140 and 142 are connected to each other via a bus (not illustrated). The DAC amplifier units 132 and 134 and the blanking aperture array mechanism 204 are connected to the deflection control circuit 130. The sub-deflector 209 includes four or more electrodes, and each electrode is controlled by the deflection control circuit 130 via the DAC amplifier unit 132. The main deflector 208 includes four or more electrodes, and each electrode is controlled by the deflection control circuit 130 via the DAC amplifier 134. A lens group including the illumination lens 202, the reduction lens 205, and the objective lens 207 is controlled by the lens control circuit 136.

The position of the XY stage 105 is controlled by driving a motor of each shaft (not illustrated) controlled by the stage control mechanism 138. The stage position measuring device 139 receives the reflected light from the mirror 210 to measure the position of the XY stage 105 by the principle of the laser interference method.

In the control computer 110, a rasterization processing unit 50, a shot data generating unit 52, a current density distribution creating unit 56, a weight coefficient setting unit 58, a correction coefficient calculating unit 60, a correcting unit 62, a writing control unit 72, and a transfer processing unit 74 are disposed.

Each “unit” such as the rasterization processing unit 50, the shot data generating unit 52, the current density distribution creating unit 56, the weight coefficient setting unit 58, the correction coefficient calculating unit 60, the correcting unit 62, the writing control unit 72, and the transfer processing unit 74 includes a processing circuit. Such a processing circuit includes, for example, an electric circuit, a computer, a processor, a circuit board, a quantum circuit, or a semiconductor device. The “units” may use a common processing circuit (the same processing circuit) or may use different processing circuits (separate processing circuits). Pieces of information input to and output from the rasterization processing unit 50, the shot data generating unit 52, the current density distribution creating unit 56, the weight coefficient setting unit 58, the correction coefficient calculating unit 60, the correcting unit 62, the writing control unit 72, and the transfer processing unit 74 and pieces of information during calculation are stored in the memory 112 each time.

The writing operation of the writing apparatus 100 is controlled by the writing control unit 72. In other words, the writing control unit 72 (an example of a control circuit) controls the writing mechanism 150. In addition, the transfer processing of beam irradiation time data of each shot to the deflection control circuit 130 is controlled by the transfer processing unit 74.

In addition, writing data (chip data) is input from the outside of the writing apparatus 100 and stored in the storage device 140. In the chip data, information of a plurality of figure patterns constituting a chip pattern is defined. Specifically, for each figure pattern, for example, the coordinates of vertices are defined in the order of forming the figure. Alternatively, for example, a figure code, coordinates, a size, and the like are defined for each figure pattern.

Here, FIG. 1 illustrates components necessary for describing the first embodiment. The writing apparatus 100 may have other components normally needed.

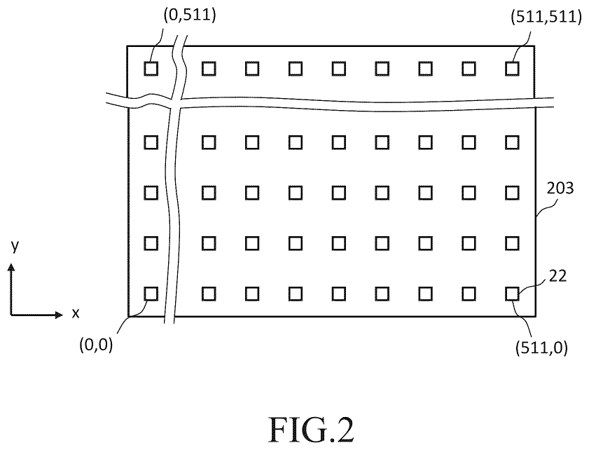

FIG. 2 is a conceptual diagram illustrating a configuration of a shaping aperture array substrate according to the first embodiment. In FIG. 2, holes (openings) 22 of p rows (x direction)×q rows (y direction) (p, q≥2) are formed in a matrix at a predetermined arrangement pitch in the shaping aperture array substrate 203. In the example of FIG. 2, for example, a case where the holes 22 of 512 rows×512 rows are formed (x and y directions) is illustrated. However, the number of the holes 22 is not limited to the above-described number. For example, the holes 22 of 32 rows×32 rows may be formed. The holes 22 are formed in a rectangular shape having the same size and shape. Alternatively, they may be circular having the same diameter. A part of an electron beam 200 passes through each of the plurality of holes 22, whereby multiple beams 20 are formed. In other words, the shaping aperture array substrate 203 forms the multiple beams 20.

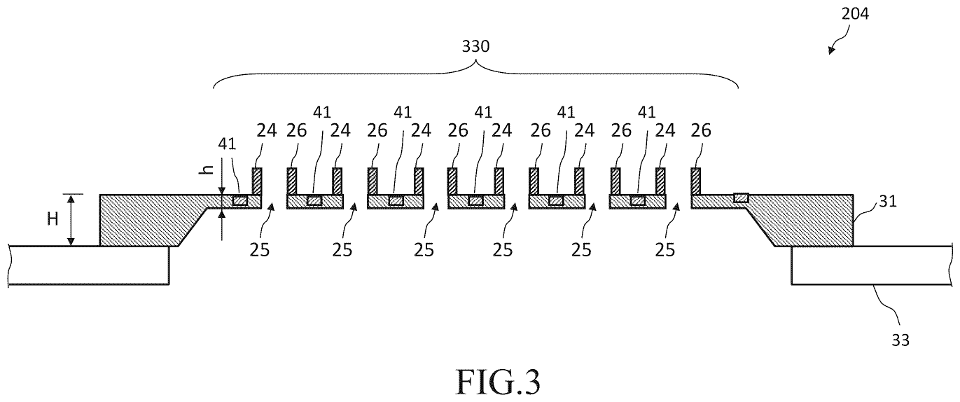

FIG. 3 is a cross-sectional view illustrating a configuration of a blanking aperture array mechanism according to the first embodiment. As illustrated in FIG. 3, in the blanking aperture array mechanism 204, a blanking aperture array substrate 31 formed by using a semiconductor substrate containing silicon or the like is positioned on a support base 33. In a membrane region 330 in the central portion of the blanking aperture array substrate 31, a passing hole 25 (opening) through which each beam of the multiple beams 20 passes is opened at a position corresponding to the hole 22 in the shaping aperture array substrate 203 illustrated in FIG. 2. Then, a pair of a control electrode 24 and a counter electrode 26 (blanker: blanking deflector) is disposed at positions facing each other across the corresponding passing hole 25 among the plurality of passing holes 25. In addition, a control circuit 41 (logic circuit) that applies a deflection voltage to the control electrode 24 for each of the passing holes 25 is arranged inside the blanking aperture array substrate 31 in the vicinity of the passing holes 25. The counter electrode 26 for each beam is grounded.

An amplifier (an example of a switching circuit) (not illustrated) is disposed in the control circuit 41. As an example of the amplifier, a complementary MOS (CMOS) inverter circuit serving as a switching circuit is disposed. Either a low (L) potential (for example, a ground potential) lower than a threshold voltage or a high (H) potential (for example, 1.5 V) equal to or higher than the threshold voltage is applied as a control signal to an input (IN) of the CMOS inverter circuit. In the first embodiment, in a state where the L potential is applied to the input (IN) of the CMOS inverter circuit, the output (OUT) of the CMOS inverter circuit applied to the control circuit 41 is controlled to have a positive potential (Vdd), so that an electric field formed by the potential difference from the ground potential of the counter electrode 26 deflects the corresponding beam, and then the beam is shielded by the limiting aperture substrate 206 to make the beam in the off state. On the other hand, in a state (active state) in which the H potential is applied to the input (IN) of the CMOS inverter circuit, the output (OUT) of the CMOS inverter circuit is controlled to have the ground potential, so that there is no potential difference from the ground potential of the counter electrode 26 and the corresponding beam is not deflected, and the beam is controlled to pass through the limiting aperture substrate 206 to make the beam in the on state. Blanking control is performed by such deflection.

Next, a specific example of the operation of the writing mechanism 150 will be described. The electron beam 200 emitted from the electron emission source 201 (emission source) illuminates the entire shaping aperture array substrate 203 almost vertically by the illumination lens 202. A plurality of rectangular holes 22 (openings) is formed in the shaping aperture array substrate 203, and the electron beam 200 illuminates a region including all of the plurality of holes 22. Each part of the electron beam 200 with which the positions of the plurality of holes 22 are irradiated passes through the corresponding one of the plurality of holes 22 of the shaping aperture array substrate 203, whereby, for example, rectangular multiple beams (a plurality of electron beams) 20 (beam array) are formed. The multiple beams 20 pass through the respective corresponding blankers of the blanking aperture array mechanism 204. Such blankers perform blanking control on the beams passing therethrough so that the beams are in the on state for a set writing time (beam irradiation time) individually.

The multiple beams 20 having passed through the blanking aperture array mechanism 204 are reduced by the reduction lens 205 and advance toward the center hole formed in the limiting aperture substrate 206. Here, the electron beams deflected by the blankers of the blanking aperture array mechanism 204 deviate from the position of the center hole of the limiting aperture substrate 206 and is shielded by the limiting aperture substrate 206. On the other hand, electron beams that are not deflected by the blankers of the blanking aperture array mechanism 204 pass through the center hole of the limiting aperture substrate 206 as illustrated in FIG. 1. In this manner, the limiting aperture substrate 206 shields each beam deflected to be in the beam off state by the blanker of the blanking aperture array mechanism 204. Then, a beam that has passed through the limiting aperture substrate 206 and been formed from the time when the beam is turned on to when the beam is turned off serves as each beam of one shot. The multiple beams 20 having passed through the limiting aperture substrate 206 are focused by the objective lens 207 to make a pattern image of a desired reduction ratio, and the entire multiple beams 20 having passed through the limiting aperture substrate 206 are collectively deflected in the same direction by the main deflector 208 and the sub-deflector 209, and the respective irradiation positions of the beams on the target object 101 are irradiated with the beams. In addition, for example, when the XY stage 105 is continuously moved, tracking control is performed by the main deflector 208 such that the irradiation position of the beam follows the movement of the XY stage 105. The multiple beams 20 emitted at a time are ideally arranged at a pitch obtained by multiplying the arrangement pitch of the plurality of holes 22 of the shaping aperture array substrate 203 by the above-described desired reduction ratio.

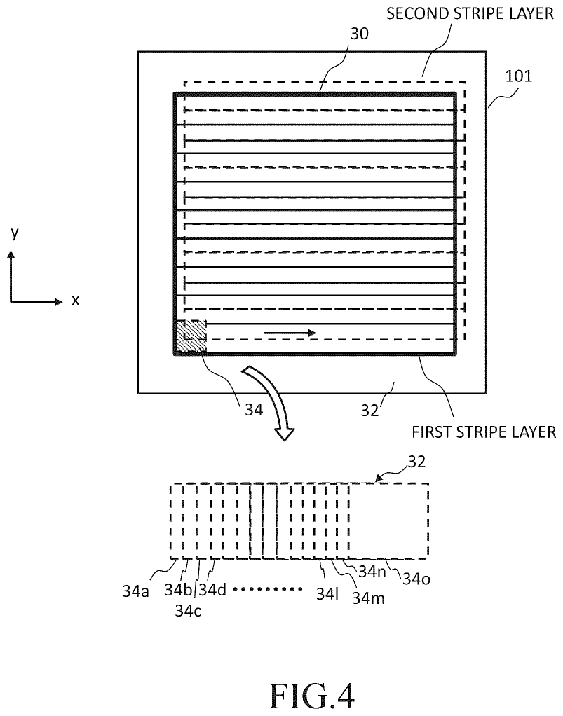

FIG. 4 is a conceptual diagram for describing an example of a writing operation in the first embodiment. As illustrated in FIG. 4, a writing region 30 (thick line) of the target object 101 is virtually divided, in, for example, the y direction into a plurality of stripe regions 32 having a stripe shape of a predetermined width. The example of FIG. 4 illustrates a case where the writing region 30 of the target object 101 is divided in, for example, the y direction into a plurality of stripe regions 32 having a width size substantially the same as the size of a designed irradiation region 34 (writing field, beam array region) that can be irradiated with the multiple beams 20 at one shot.

In the example of FIG. 4, a case where multiple writing of, for example, multiplicity 2 is performed is illustrated. A first stripe layer including a plurality of stripe regions 32 obtained by dividing the writing region 30 is set for a first writing process. In addition, a second stripe layer including a plurality of stripe regions 32, the positions of which are shifted in the y direction from the first stripe layer is set for the second writing process. The shift amount in the x and y directions between passes when multiple writing is performed is set depending on the multiplicity, for example. For example, when the multiplicity is N, it is preferable to shift the position by 1/N of the width of the stripe regions 32 between passes. The multiplicity is not limited to 2, and may be 3 or more. The passes in multiple writing refer to stage movements when multiple writing is performed on a stripe region 32 of the same number by repeatedly moving the stage.

In the multiple writing, the multiple writing may be performed by writing the same pixel a plurality of times in the same pass, in other words, during one stage travel.

In the example of FIG. 4, the position is shifted in both the x and y directions, but the present invention is not limited thereto. The position may be shifted only in the x direction between multiple writing passes. Alternatively, the position may be shifted only in the y direction between multiple writing passes. Next, an example of the writing operation will be described.

First, the XY stage 105 is moved and adjusted such that the irradiation region 34 of the multiple beams 20 is positioned at the left end of the first stripe region 32 of the first stripe layer or at a position on the further left side. When writing on the first stripe region 32 is performed, the XY stage 105 is moved in, for example, the −x direction to relatively advance the writing in the x direction. The XY stage 105 is continuously moved at a constant speed, for example.

After the writing on the first stripe region 32 of the first stripe layer is completed, the stage position is moved in the −y direction by, for example, 1/N of the width of the stripe region 32. As a result, the stripe region 32 on which writing is performed is shifted by, for example, 1/N of the width of the stripe region 32 in the y direction. In the example of FIG. 4, since a case where multiple writing is performed in two passes is illustrated, the stage position is shifted by, for example, ½ of the width of the stripe region 32 in the y direction.

Next, the XY stage 105 is adjusted such that the irradiation region 34 of the multiple beams 20 is positioned at the left end of the first stripe region 32 of the second stripe layer or at a position on the further left side. Then, by moving the XY stage 105 in, for example, the −x direction, writing is relatively advanced in the x direction. As a result, writing on the first stripe region 32 of the second stripe layer is performed. After the writing on the first stripe region 32 of the second stripe layer is completed, writing on the second stripe region 32 of the first stripe layer is performed. In this manner, the corresponding stripe regions 32 of stripe layers are sequentially written. Thereafter, the operation is similarly repeated to perform writing on all the stripe regions 32 of the stripe layers is performed.

In the example of FIG. 4, the case where the writing is advanced on the stripe regions 32 in the same direction is illustrated, but the present invention is not limited thereto. For example, for the stripe region 32 to be written next to the stripe region 32 on which writing has been advanced in the x direction, writing may be performed, for example, in the −x direction by moving the XY stage 105 in the x direction. By performing writing while alternately changing the directions in this manner, the stage moving time can be shortened, and the writing time can be shortened accordingly. In one shot, the multiple beams formed by the electron beam having passed through the holes 22 of the shaping aperture array substrate 203 form a plurality of shot patterns as many as the holes 22 at maximum at one time.

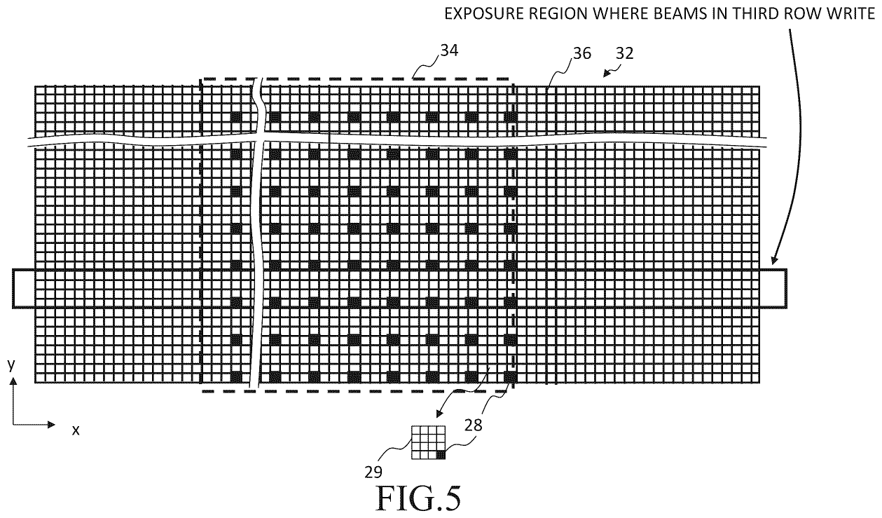

FIG. 5 is a diagram illustrating an example of an irradiation region of multiple beams and a writing target pixel in the first embodiment. In FIG. 5, the stripe regions 32 are divided into a plurality of mesh regions having the beam size of the multiple beams 20 in a mesh shape, for example. Each of the mesh regions serves as a writing target pixel 36 (beam irradiation unit region, irradiation position, position). The size of the writing target pixel 36 is not limited to the beam size, and may be any size regardless of the beam size. For example, the beam size may be 1/n (n is an integer of 1 or more) of the beam size. The example of FIG. 5 illustrates a case where the writing region of the target object 101 is divided in, for example, the y direction into a plurality of stripe regions 32 having a width size substantially the same as the size of an irradiation region 34 (writing field) that can be irradiated with the multiple beams 20 at one shot. The size of the rectangular irradiation region 34 in the x direction can be defined by the number of beams in the x direction x inter-beam pitch in the x direction. The size of the rectangular irradiation region 34 in the y direction can be defined by the number of beams in the y direction×inter-beam pitch in the y direction. In the example of FIG. 5, for example, the illustration of multiple beams of 512 rows×512 rows is illustrated as multiple beams of 8 rows×8 rows for simplification. In the irradiation region 34, a plurality of pixels 28 (beam writing positions) that can be irradiated with one shot of the multiple beams 20 is illustrated. The pitch between the adjacent pixels 28 is the inter-beam pitch of the multiple beams. One sub-irradiation region 29 (pitch cell region) is configured by a rectangular region of the size of the inter-beam pitch in the x and y directions. In the example of FIG. 5, a case where each sub-irradiation region 29 includes, for example, 4×4 pixels is illustrated.

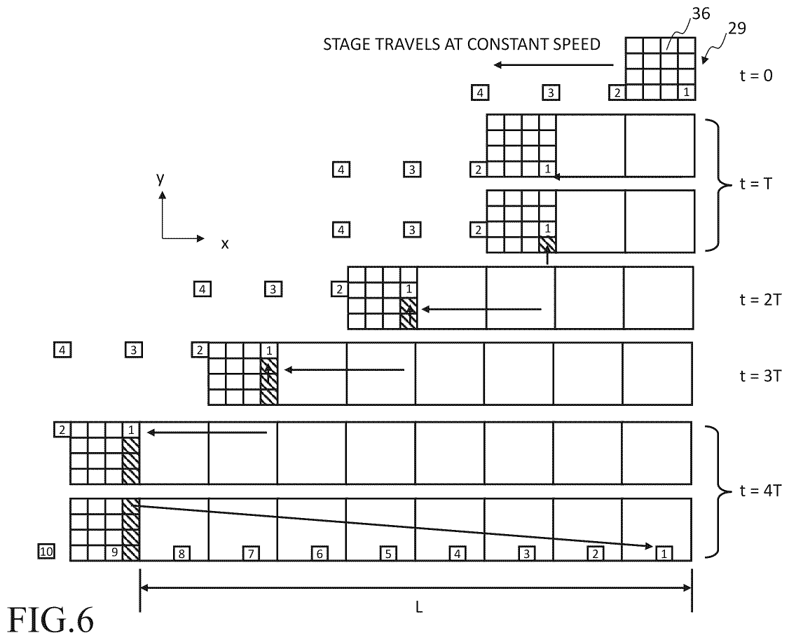

FIG. 6 is a diagram for describing an example of a multiple beam writing operation in the first embodiment. In the example of FIG. 6, a case where writing on each of the sub-irradiation regions 29 is performed with four different beams is illustrated. In addition, the example of FIG. 6 illustrates a writing operation in which the XY stage 105 continuously moves at a speed of moving by the distance L corresponding to the 8 beam pitches during writing on ¼ of each sub-irradiation region 29 (a part obtained by dividing the sub-irradiation region 29 by the number of beams used for irradiation). In the writing operation illustrated in the example of FIG. 6, for example, four different pixels in the same sub-irradiation region 29 are written (exposed) by four shots of the multiple beams 20 at a shot cycle T while sequentially shifting the irradiation positions (pixels 36) by the sub-deflector 209 during movement of the XY stage 105 by the distance L corresponding to 8 beam pitches. While such four pixels are written (exposed), the entire multiple beams 20 are collectively deflected by the main deflector 208 such that the irradiation region 34 is not displaced relative to the target object 101 due to the movement of the XY stage 105, making the irradiation region 34 follow the movement of the XY stage 105. In other words, tracking control is performed. When one tracking cycle ends, tracking is reset, and the irradiation region 34 returns to the previous tracking start position. Since the writing of the first pixel column from the right of each sub-irradiation region 29 is completed, after the tracking is reset, in the next tracking cycle, the sub-deflector 209 first deflects the beams to adjust (shift) the beam writing position to a pixel column of the sub-irradiation region 29, which has not been written and can be, for example, the second pixel column from the right. Writing is performed by repeating such an operation during writing of the stripe region 32 to sequentially move the position of the irradiation region 34 of the multiple beams 20 as illustrated as irradiation regions 34a, 34b, 34c, . . . , and 340 in the lower diagram of FIG. 4.

For example, in the example of FIG. 6, when the writing process is performed with 32× 32 multiple beams 20, each pixel 36 is written once during one stage travel. When the same operation is performed with the multiple beams 20 of 512 rows×512 rows, each of the sub-irradiation regions 29 includes 16×16 pixels. Then, 16 different pixels in the same sub-irradiation region 29 are written (exposed) by 16 shots of the multiple beams 20 at the shot cycle T while sequentially shifting the irradiation positions (pixels 36) by the sub-deflector 209 during movement of the XY stage 105 by the distance L corresponding to 32 beam pitches. After the tracking is reset, the irradiation position is adjusted to the column next to the column in which the writing is completed in each of the sub-irradiation regions 29. By repeating such an operation, each pixel 36 is written once during one stage travel (per pass).

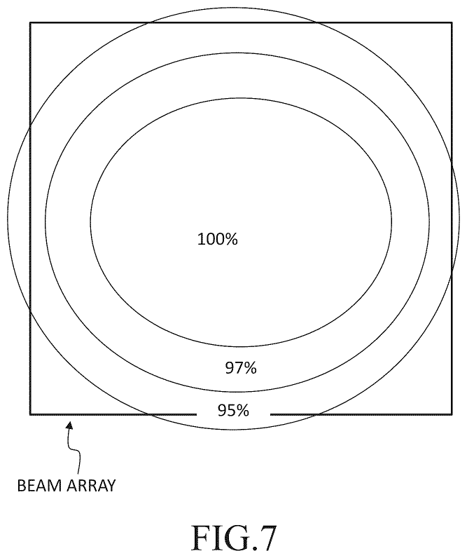

FIG. 7 is a diagram illustrating an example of the current density distribution in the first embodiment. The current densities of the beams of the multiple beams 20 constituting the beam array are not uniform. For example, as illustrated in FIG. 7, the current density decreases radially outward as compared with the beam group in the central portion. In the example of FIG. 7, the current density of the beam group in the central portion is 100%, whereas the current density is 97% outside the beam group, the current density is 95% further outside, and the current density is further reduced further outside. Therefore, even if the target object surface is irradiated with the beams of the same beam irradiation time, the dose incident on the target object is different.

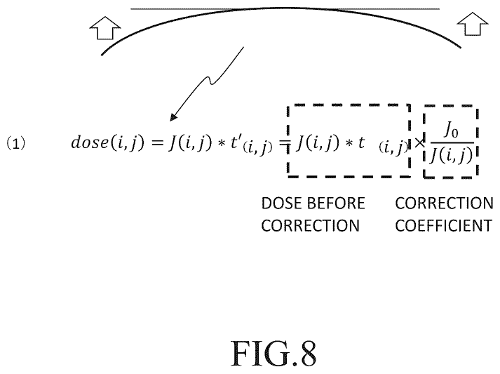

FIG. 8 is a diagram for describing a method of correcting a deviation in beam irradiation time due to a difference in current density in a first comparative example of the first embodiment. In the first comparative example, for a beam having a small current density, an error in the current density is corrected with a correction coefficient so as to obtain an ideal current density. Specifically, a beam irradiation time t(i, j) is corrected using, for example, a ratio (J₀/J(i, j)) of the ideal current density J₀ as 100% to a current density J(i, j) of each beam, as a correction coefficient. (i, j) is an index indicating an arrangement position of each beam in the beam array. The dose, dose (i, j) can be defined by Formula (1) below.

$$dose ( i , j ) = J ( i , j ) * {t}^{′} ( i , j ) = J ( i , j ) * t ( i , j ) \times \frac{{J}_{0}}{J ( i , j )} \qquad ( 1 )$$

Since the dose, dose (i, j) is calculated by the product of the current density J(i, j) and the beam irradiation time as indicated by Formula (1), the dose can be matched with the designed dose, dose (i, j) by multiplying the product of the beam irradiation time t(i, j), before correction calculated with the ideal current density, and the current density J(i, j) by the correction coefficient (J₀/J(i, j)). Since the writing process is controlled by the beam irradiation time, the beam irradiation time t(i, j) after correction obtained by multiplying the beam irradiation time t(i, j) before correction by the correction coefficient (J₀/J(i, j)) may be used.

However, in the first comparative example, when a beam having a singularly small current density is generated in the beam array, the correction coefficient of the beam becomes singularly large. In the multi-beam writing, a shot cycle is set in accordance with the longest beam irradiation time. Therefore, if there is a singular correction coefficient, the shot cycle for all shots becomes long, and the writing time becomes long. As a result, the throughput is degraded.

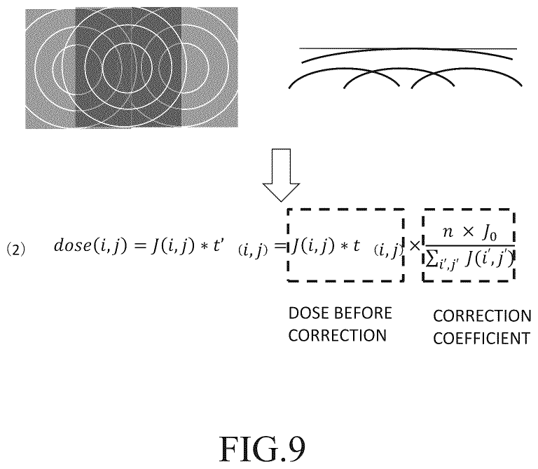

FIG. 9 is a diagram for describing a method of correcting a deviation in beam irradiation time due to a difference in current density in a second comparative example of the first embodiment. As illustrated in FIG. 9, multiple writing is performed while shifting the position of the beam array. In the example of FIG. 9, a case where multiple writing is performed while shifting the beam array by half in the x direction is illustrated. In this case, each pixel in the target object surface is irradiated with a plurality of beams at different arrangement positions. In the second comparative example, the current densities J(i, j) of a plurality of beams at different arrangement positions used for the same pixel in the respective passes of multiple writing are averaged. The dose, dose (i, j) in the second comparative example can be defined by Formula (2) below.

$$dose ( i , j ) = J ( i , j ) * {t}^{′} ( i , j ) = J ( i , j ) * t ( i , j ) \times \frac{n \times {J}_{0}}{{Σ}_{{i}^{′} , {j}^{′}} J ( {i}^{′} , {j}^{′} )} \qquad ( 2 )$$

As indicated by Expression (2), the designed dose of each pass is corrected using, as a correction coefficient, a ratio obtained by dividing the ideal current density J₀ by the averaged current density (ΣJ(i, j)/n). n represents the number of current densities to be averaged. In other words, n indicates the multiplicity N. As a result, the singular current density can be averaged, so that the singular beam irradiation time can be suppressed.

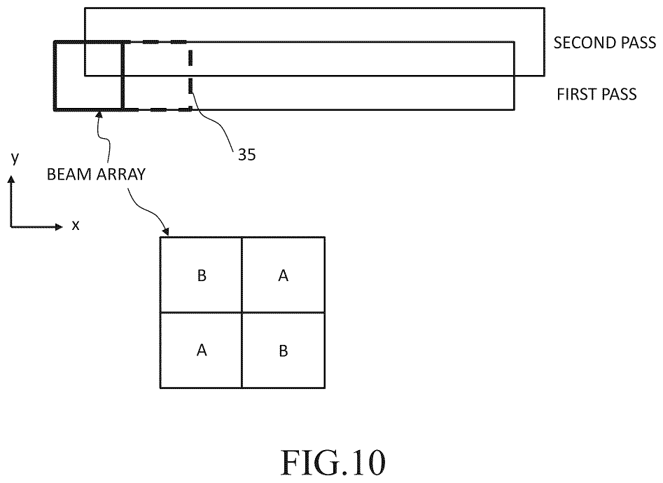

FIG. 10 is a diagram for describing an example of multiple writing of multiplicity 2 in the first embodiment. The example of FIG. 10 illustrates a case where the multiplicity N is 2. In the second pass, the beam array is shifted by ½ of the width size of the stripe region 32 from the first pass in the x and y directions, and writing is performed. In each stripe region 32, writing is repeated under the same beam condition in a plurality of rectangular regions 35 obtained by dividing the stripe region 32 in the x direction into the same size as the irradiation region 34 of the beam array. Therefore, when multiple writing is performed while shifting the beam array in the x and y directions by ½ of the width size of the stripe region 32, two beam groups in blocks of the same symbol in four blocks obtained by dividing the irradiation region of the beam array into 2×2 blocks write the same region of the stripe region 32 in different passes of multiple writing. The two blocks A at the lower left position and the upper right position indicate that a region written by the beam group of the upper right block A in the first pass is written by the lower left block A in the second pass. In other words, pixels irradiated with beams in the upper right block A are irradiated with beams at the corresponding arrangement positions in the lower left block A.

Here, in the second comparative example, the correction coefficients of the two beams with which the same pixel is irradiated are the same due to the averaging indicated by Formula (2). The designed beam irradiation time for each pass in multiple writing is generally set to the same value. Therefore, the beam irradiation time after the correction is likely to be the same. As a result, due to the quantization error generated when the beam irradiation time is quantized in a predetermined quantization unit, the error of the dose controlled by the beam irradiation time also acts in the same direction. It is assumed that the beam irradiation time of a pixel for each pass is normalized to, for example, 1.5 with the base irradiation time set to 1. It is assumed that the quantization error at that time is +0.1, for example. In such a case, in multiple writing in which writing is repeated with the same beam irradiation time, such a quantization error is accumulated. For example, a quantization error of +0.2 is generated in the case of the multiplicity 2, and a quantization error of +0.4 is generated in the case of the multiplicity 4. Therefore, in the case of multiplicity 4, a dose error corresponding to 0.4× current density is generated in a direction in which the dose excessively increases. Conversely, it is assumed that the quantization error is −0.1, for example. In such a case, in multiple writing in which writing is repeated with the same beam irradiation time, such a quantization error is accumulated. For example, a quantization error of −0.2 is generated in the case of the multiplicity 2, and a quantization error of −0.4 is generated in the case of the multiplicity 4. Therefore, in the case of multiplicity 4, a dose error corresponding to 0.4× current density is generated in a direction in which the dose is insufficient.

Therefore, in the first embodiment, in multiple writing, two or more kinds of weights are applied to a plurality of beams with which pixels are irradiated to differ the beam irradiation times in passes. Hereinafter, a specific description will be given.

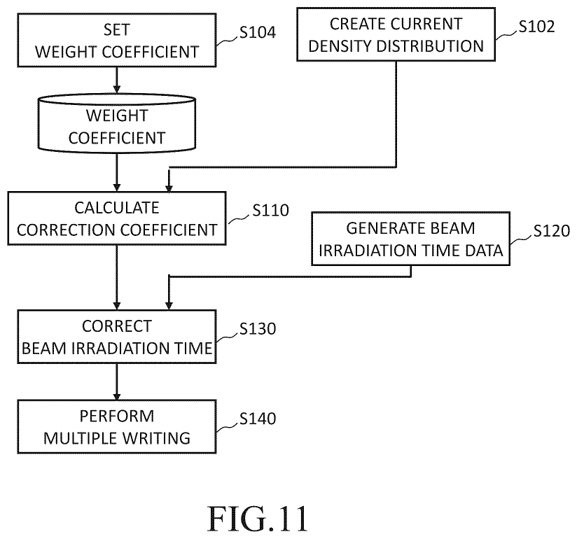

FIG. 11 is an example of a flowchart illustrating main steps of the writing method according to the first embodiment. In FIG. 11, the writing method according to the first embodiment includes a series of steps including a current density distribution creating step (S102), a weight coefficient setting step (S104), a correction coefficient calculating step (S110), a beam irradiation time data generating step (S120), a beam irradiation time correcting step (S130), and a writing step (S140).

As the current density distribution creating step (S102), first, the current density is measured for each beam of the multiple beams 20 under the control of the writing control unit 72. For example, beams other than target beams are controlled to be in the off state, and the target beams are incident on the Faraday cup 106. As a result, the current values of the beams can be measured. The measurement result of each beam is output to the control computer 110 via a detection circuit (not illustrated). The current density distribution creating unit 56 creates a current density distribution in which the current density for each beam is defined as an element. For example, a current density map is created. The current density may be calculated by dividing the measured current value by the cross-sectional area of the beam. When the diameters of the holes (openings) 22 of the shaping aperture array substrate 203 vary, the current amount for each beam in consideration of the variation in the hole diameter may be defined as an element. The created current density distribution (current amount distribution) is stored in the storage device 142. Here, the current density of each beam will be described as an example of the current amount of each beam.

As the weight coefficient setting step (S104), the weight coefficient setting unit 58 sets one of the plurality of weight coefficients x for each beam of the multiple beams 20 according to the arrangement positions (i, j) of the multiple beams 20.

FIG. 12 is a diagram for describing an example of multiple writing of multiplicity 4 in the first embodiment. The example of FIG. 12 illustrates a case where the multiplicity N is 4. Between passes, the beam array is shifted in the x and y directions by ¼ of the width size of the stripe region 32 from the previous pass and writing is performed. In each stripe region 32, writing is repeated under the same beam condition in a plurality of rectangular regions 35 obtained by dividing the stripe region 32 in the x direction into the same size as the irradiation region 34 of the beam array. Therefore, when multiple writing is performed while shifting the beam array in the x and y directions by ¼ of the width size of the stripe region 32, beam groups in blocks of the same symbol in 16 blocks A to D obtained by dividing the beam array into 4×4 blocks write the same region of the stripe region 32.

Therefore, the beam groups in each of the four blocks of the symbol A among the plurality of blocks in the beam array write the same region of the stripe region 32 in different passes. In other words, the same pixel is irradiated with beams of corresponding arrangement positions in blocks of the same symbol (for example, A). If the correction coefficients of the four beams with which the same pixel are irradiated are averaged to the same value as in the second comparative example, the above-described quantization error is generated. Therefore, the weight coefficient setting unit 58 sets weight coefficients for beams such that correction coefficients are different in at least two passes among the passes.

In the first embodiment, multiple writing is performed for the same pixel 36 of the target object 101 by a plurality of beams at different arrangement positions for which two or more kinds of weighting coefficients α (i, j) are set among the multiple beams 20. The doses, dose (i, j) of the beams in passes in such a case can be defined, for each beam of the beams of a plurality of beams with which the pixel 36 is irradiated, using two or more kinds of weighting coefficients α (i, j) of the plurality of beams for writing the pixel 36 and the current amounts of the beams of the plurality of beams, for example, the current densities J(i, j). The dose, dose (i, j) of the beam of each pass can be defined by Formula (3) below. In Formula (3), the current density J(i, j) of each beam is used, but instead of the current density J(i, j), the current amount I (i, j) of each beam may be used.

$$dose ( i , j ) = J ( i , j ) * {t}^{′} ( i , j ) = J ( i , j ) * t ( i , j ) \times \frac{n \times {J}_{0}}{1 / α ( i , j ) \times {Σ}_{{i}^{′} , {j}^{′}} α ( {i}^{′} , {j}^{′} ) \times J ( {i}^{′} , {j}^{′} )} \qquad ( 3 )$$

The weighting coefficients x (i, j) in Formula (3) set for beams with which the same pixel is irradiated are independently set regardless of the current amounts of the beams, for example, the current densities J(i, j). In addition, a weighting coefficient x (i, j) is set for each beam such that a total value of doses (exposure intensities) of a plurality of beams with which each pixel 36 of the target object 101 is irradiated becomes a designed value. Note that deviation from the designed value of the total value to an extent that does not affect the writing accuracy is allowed.

In Formula (3), when the current density J is averaged between the passes, values each obtained by multiplying the current density J of the beam by the weighting coefficient of the beam are summed for each pass. Then, the sum is further divided by the weighting coefficient of the beam. Simply multiplying the averaged correction coefficient described in the second comparative example by the weighting coefficient results in deviation from the designed dose. Therefore, when the correction is performed using the weighting coefficients, the designed dose can be obtained by performing correction in association with the current densities J as expressed in Formula (3). Specific examples will be described below.

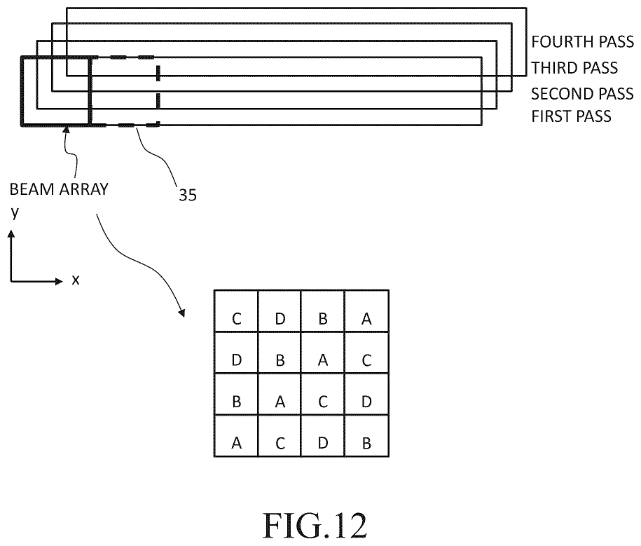

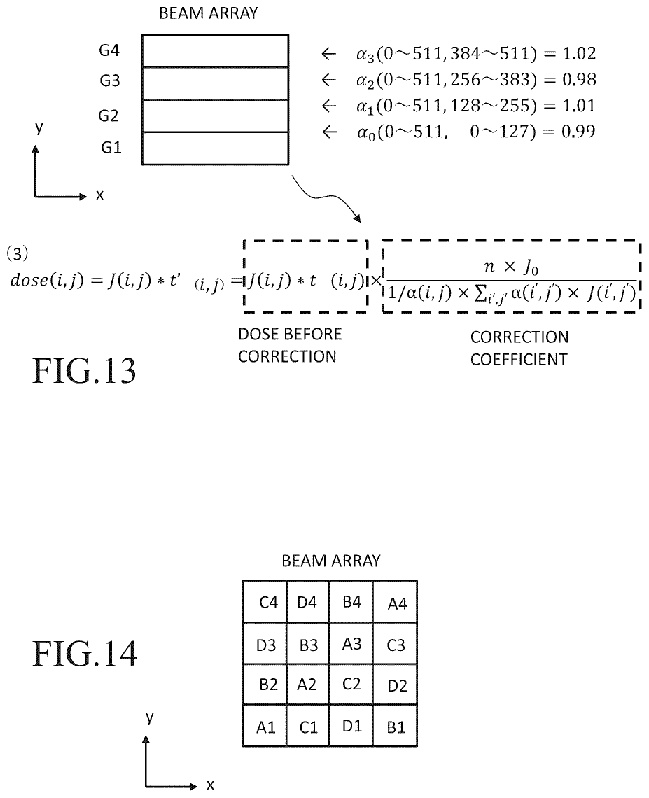

FIG. 13 is a diagram illustrating an example of group regions of weighting coefficients in the first embodiment. In the example of FIG. 13, a case of multiple writing with the multiplicity 4 in which the position of the beam array is shifted in the x and y directions by ¼ of the width size of the stripe region 32 is illustrated. The example of FIG. 13 illustrates a case where different weighting coefficients are set for a plurality of beams with which the same position of the target object 101 is irradiated. Hereinafter, a specific description will be given. Note that the “same position” does not necessarily indicate exactly the same position, and there may be a positional shift of the beams or a shift of a designed writing (irradiation) positions, and it is sufficient that the “same positions” are positions where parts of the beams overlap at least in part.

In the example of FIG. 13, the beam array is divided into four group regions in the y direction. Then, for example, a group region G1, a group region G2, a group region G3, and a group region G4 are set for the beam groups in the region from the lower region. In the case of the multiple beams 20 of 512 rows×512 rows, the arrangement positions (i, j) of the beams are defined by 0 to 511 for both i and j.

The weighting coefficients α are preferably prepared as many as the multiplicity N of multiple writing, for example. The plurality of weighting coefficients may include 1. In addition, two or more different numerical values are included as the plurality of weighting coefficients. For example, in the case of the multiplicity 4, four weighting coefficients of four kinds of, for example, 0.98, 0.99, 1.01, and 1.02 are used as a. As described above, it is preferable to set all the four weighting coefficients to different values. However, the weighting coefficients are not limited to those described above. As a, 1 may be included, and the weighting coefficients may be 0.97, 1.00, 1.01, and 1.02, for example. Alternatively, the same numerical value may be used for some of the weighting coefficients as long as the weighting coefficients include two or more kinds of values, and the weighting coefficients may be 0.99, 1.01, 0.99, and 1.01, for example. In the case of the multiplicity 2, for example, two weighting coefficients of 0.99 and 1.01 are used as a. In addition, the range of the weighting coefficient is not particularly limited, but in consideration of the quantization error, the difference between the plurality of weighting coefficients is preferably in the order of 1/M (M is the gradation number of the dose). For example, the weighting coefficients can be set in units of 1/100, and are preferably set in a range of 0.95 to 1.05.

In any case, the total value of the weighting coefficients of each pass applied to the same pixel is set to match with the value of the multiplicity. In the above-described example, in the case where, for example, 0.98, 0.99, 1.01, and 1.02 are set as a, the sum is 4, which matches with the multiplicity 4. As a result, the total value of the doses (exposure intensities) of the plurality of beams with which each pixel 36 is irradiated can be set as the design value.

The plurality of weighting coefficients α may be determined in advance for each multiplicity. The data of the set of the weight coefficients for each multiplicity may be stored in the storage device 140.

In the example of FIG. 13, the weight coefficient setting unit 58 sets a beam group (beams in the first region from the bottom) at arrangement positions of (0 to 511, 0 to 127) as the group region G1, and sets the weight coefficient α0=0.99 to each beam in the group region G1.

The weight coefficient setting unit 58 sets a beam group (beams in the second region from the bottom) at arrangement positions of (0 to 511, 128 to 255) as the group region G2, and sets a weight coefficient α1=1.01 for each beam in the group region G2.

The weight coefficient setting unit 58 sets a beam group (beams in the third region from the bottom) at arrangement positions of (0 to 511, 256 to 383) as the group region G3, and sets a weight coefficient α2=0.98 for each beam in the group region G3.

The weight coefficient setting unit 58 sets a beam group (beams in the fourth region from the bottom) at arrangement positions of (0 to 511, 384 to 511) as the group region G4, and sets a weight coefficient α3=1.02 for each beam in the group region G4.

As described above, in the multiple writing performed with multiple beams, writing in the same region is repeated for each block of the beam array. Therefore, if different weighting coefficients are set for blocks of the same symbol, the weighting coefficients of a plurality of beams with which the same position is irradiated in the respective passes can be set to different values. In the example of FIG. 12, the position is shifted between passes also in the x direction, so that the block is also divided into four blocks A to D in the x direction, but it is sufficient that the weighting coefficients vary in units of four group regions divided in the y direction. As described above, by setting the weighting coefficient for each group region including a plurality of beams, the number of weighting coefficients can be reduced as compared with a case where the weighting coefficient is individually set for each beam. Alternatively, weighting coefficients may be set for beams such that different correction coefficients are set for the respective blocks that are more than the number of group regions. Alternatively, weighting coefficients may be set for beams such that different correction coefficients are set for the respective sub-blocks obtained by further subdividing the blocks. For example, each block may be suitably divided into 4×4 sub-blocks. Alternatively, weighting coefficients may be set for beams such that the correction coefficients for the respective beams are different.

In the example of FIG. 12, in the first pass, for example, a sub-region in the stripe region 32 is irradiated with the beam group of the uppermost block A among the four blocks A, and then α3=1.02 is applied to the beam group of the uppermost block A. In the second pass, the same sub-region is irradiated with the beam group of the block A in the second row from the top, α2=0.98 is applied to the beam group of the block A in the second row from the top. In the third pass, α1=1.01 is applied. Then, in the fourth pass, α0=0.99 is applied. Therefore, the four blocks A irradiate the same region in different passes of multiple writing, but the weighting coefficients vary between the passes. Alternatively, at least two kinds of weighting coefficients are applied in the four passes.

As the correction coefficient calculating step (S110), when multiple writing is performed on the same pixel 36 (position) of the target object 101 as a writing target with a plurality of beams at different arrangement positions, for which two or more types of weighting coefficients x are set, among the multiple beams 20, the correction coefficient calculating unit 60 calculates a correction coefficient K for correction for each beam of a plurality of beams with which the pixel 36 is irradiated, using two or more kinds of weighting coefficients α for the plurality of beams with which the pixel 36 is written and a current density J(i, j) of each beam of the plurality of beams.

As illustrated in FIG. 13 and as can be seen from Formula (3), the correction coefficient K can be defined by Formula (4) below using the weighting coefficients α (i, j) of the beams used in the respective passes, the ideal current density J₀, and the current densities J(i, j) of the beams used in each pass.

$$K = \frac{n \times {J}_{0}}{1 / α ( i , j ) \times {Σ}_{{i}^{′} , {j}^{′}} α ( {i}^{′} , {j}^{′} ) \times J ( {i}^{′} , {j}^{′} )} \qquad ( 4 )$$

Data of the calculated correction coefficients of the respective beams is stored in the storage device 142.

FIG. 14 is a diagram illustrating an example of a block configuration in a beam array according to the first embodiment. The example of FIG. 14 illustrates a case where the multiplicity N is 4. Between passes, the beam array is shifted in the x and y directions by ¼ of the width size of the stripe region 32 from the previous pass and writing is performed. In each stripe region 32, writing is repeated under the same beam condition in a plurality of rectangular regions 35 obtained by dividing the stripe region 32 in the x direction into the same size as the irradiation region 34 of the beam array. Therefore, when multiple writing is performed while shifting the beam array in the x and y directions by ¼ of the width size of the stripe region 32, beam groups in blocks of the same symbol in 16 blocks A to D obtained by dividing the beam array into 4×4 blocks write the same region of the stripe region 32.

Therefore, the beam groups in the four blocks of the symbol A (A1 to A4) among the plurality of blocks in the beam array write the same region of the stripe region 32 in different passes. In other words, the same pixel is irradiated with beams of corresponding arrangement positions in blocks of the same symbol (for example, A). The operation described above is similar to the case of FIG. 12.

Here, in the example of FIG. 14, the weighting coefficients vary for the respective group regions, and thus even in the blocks of the same symbol A, different correction coefficients can be set for the block A1, the block A2, the block A3, and the block A4. Therefore, even when a quantization error is generated, averaging can be performed in multiple writing instead of simply accumulating quantization errors in one direction. Similarly, in the blocks of the same symbol B, different correction coefficients can be set for the block B1, the block B2, the block B3, and the block B4. Therefore, even when a quantization error is generated, averaging can be performed in multiple writing instead of simply accumulating quantization errors in one direction. Similarly, in the blocks of the same symbol C, different correction coefficients can be set for the block C1, the block C2, the block C3, and the block C4. Therefore, even when a quantization error is generated, averaging can be performed in multiple writing instead of simply accumulating quantization errors in one direction. Similarly, in the blocks of the same symbol D, different correction coefficients can be set for the block D1, the block D2, the block D3, and the block D4. Therefore, even when a quantization error is generated, averaging can be performed in multiple writing instead of simply accumulating quantization errors in one direction.

In the example of FIG. 13 described above, a case where a plurality of group regions obtained by dividing the beam array in the y direction is set has been described, but the present invention is not limited thereto.

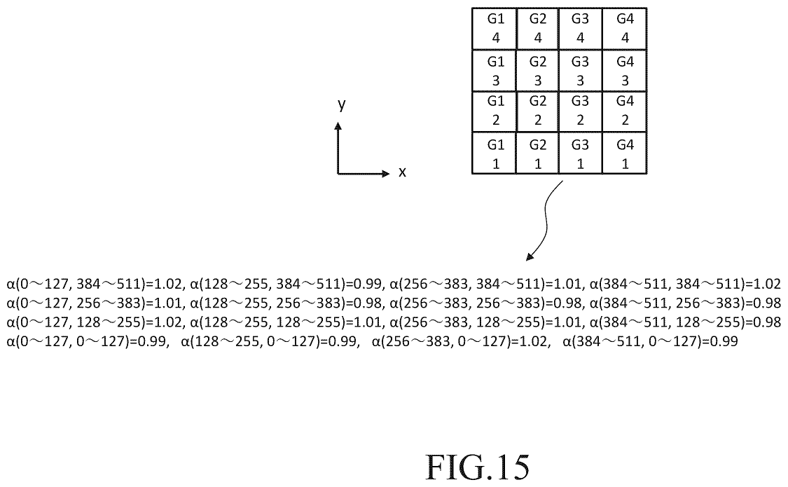

FIG. 15 is a diagram illustrating another example of group regions of the weighting coefficients in the first embodiment. In FIG. 15, the beam array is further divided in the x direction in addition to the y direction in the case of FIG. 13. In the example of FIG. 15, the beam array is divided into four group regions in the x direction, so that the beam array is divided into 16 group regions G11 to G44 of 4 rows×4 rows. Then, a weighting coefficient is set for each group region. At that time, the weighting coefficients are adjusted between groups that write the same region in different passes in multiple writing. In other words, the weighting coefficients are adjusted between the group regions G11, G22, G33, and G44 (corresponding to the blocks A1, A2, A3, and A4) that write the same region. Similarly, the weighting coefficients are adjusted between the group regions G41, G12, G23, and G34 (corresponding to the blocks B1, B2, B3, and B4) that write the same region. Similarly, the weighting coefficients are adjusted between the group regions G21, G32, G43, and G14 (corresponding to the blocks C1, C2, C3, and C4) that write the same region. Similarly, the weighting coefficients are adjusted between the group regions G31, G42, G13, and G24 (corresponding to the blocks D1, D2, D3, and D4) that write the same region.

In the example of FIG. 15, the weight coefficient setting unit 58 sets a beam group of beams at arrangement positions of (0 to 127, 0 to 127) as the group region G11, and sets the weight coefficient α11=0.99 for each beam in the group region G11.

The weight coefficient setting unit 58 sets a beam group of beams at arrangement positions of (128 to 255, 0 to 127) as the group region G21, and sets a weight coefficient α21=0.99 for each beam in the group region G21.

The weight coefficient setting unit 58 sets a beam group of beams at arrangement positions of (256 to 383, 0 to 127) as the group region G31, and sets a weight coefficient α31=1.02 for each beam in the group region G31.

The weight coefficient setting unit 58 sets a beam group of beams at arrangement positions of (384 to 511, 0 to 127) as the group region G41, and sets a weight coefficient α41=0.99 for each beam in the group region G41.

The weight coefficient setting unit 58 sets a beam group of beams at arrangement positions of (0 to 127, 128 to 255) as the group region G12, and sets a weight coefficient α12=1.02 for each beam in the group region G12.

The weight coefficient setting unit 58 sets a beam group of beams at arrangement positions of (128 to 255, 128 to 255) as the group region G22, and sets a weight coefficient α22=1.01 for each beam in the group region G22.

The weight coefficient setting unit 58 sets a beam group of beams at arrangement positions of (256 to 383, 128 to 255) as the group region G32, and sets a weight coefficient α32=1.01 for each beam in the group region G32.

The weight coefficient setting unit 58 sets a beam group of beams at arrangement positions of (384 to 511, 128 to 255) as the group region G42, and sets a weight coefficient α42=0.98 for each beam in the group region G42.

The weight coefficient setting unit 58 sets a beam group of beams at arrangement positions of (0 to 127, 256 to 383) as the group region G13, and sets a weight coefficient α13=1.01 for each beam in the group region G13.

The weight coefficient setting unit 58 sets a beam group of beams at arrangement positions of (128 to 255,256 to 383) as the group region G23, and sets a weight coefficient α23=0.98 for each beam in the group region G23.

The weight coefficient setting unit 58 sets a beam group of beams at arrangement positions of (256 to 383, 256 to 383) as the group region G33, and sets a weight coefficient α33=0.98 for each beam in the group region G33.

The weight coefficient setting unit 58 sets a beam group of beams at arrangement positions of (384 to 511, 256 to 383) as the group region G43, and sets a weight coefficient α43=0.98 for each beam in the group region G43.

The weight coefficient setting unit 58 sets a beam group of beams at arrangement positions of (0 to 127, 384 to 511) as the group region G14, and sets a weight coefficient α14=1.02 for each beam in the group region G14.

The weight coefficient setting unit 58 sets a beam group of beams at arrangement positions of (128 to 255, 384 to 511) as the group region G24, and sets a weight coefficient α24=0.99 for each beam in the group region G24.

The weight coefficient setting unit 58 sets a beam group of beams at arrangement positions of (256 to 383, 384 to 511) as the group region G34, and sets a weight coefficient α34=1.01 for each beam in the group region G34.

The weight coefficient setting unit 58 sets a beam group of beams at arrangement positions of (384 to 511, 384 to 511) as the group region G44, and sets a weight coefficient α44=1.02 for each beam in the group region G44.

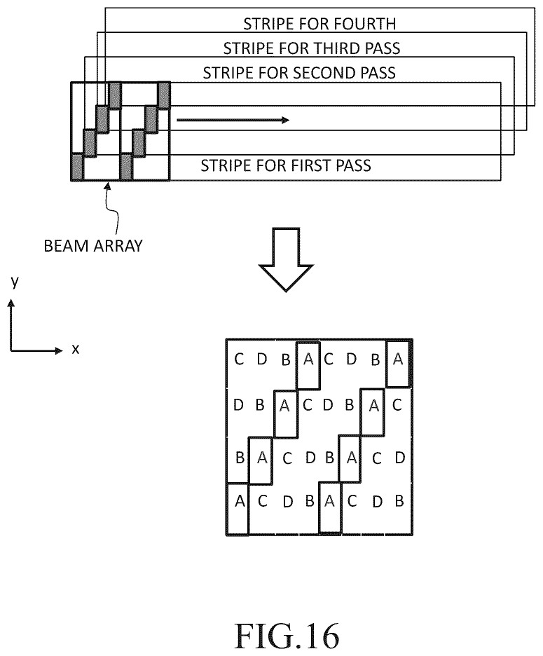

FIG. 16 is a diagram for describing how to perform multiple writing according to a modification of the first embodiment. In the example of FIG. 16, multiple writing is performed in the same pass. In the example of FIG. 16, multiple writing is performed in the left half and the right half of the beam array. For example, in the case of writing with the multiple beams 20 of 512 rows×512 rows, each sub-irradiation region 29 is configured by, for example, 16×16 pixels. In such a case, while the XY stage 105 moves by the distance L corresponding to 16 beam pitches, 16 shots of the multiple beams 20 are performed at the shot cycle T while sequentially shifting the irradiation positions (pixels 36) by the sub-deflector 209, so that different 16 pixels in the same sub-irradiation region 29 are written (exposed). As a result, the region written by the right half of the beam array can be multiply written by the left half of the beam array.

The example of FIG. 16 illustrates a case where the multiplicity N is 8. Multiple writing is performed eight times in total, that is, twice in each of four passes. Between the passes, the beam array is shifted in the y direction by ¼ of the width size of the stripe region 32 and in the x direction by ⅛ of the width size from the previous pass and writing is performed. In each stripe region 32, writing is repeated under the same beam condition in a plurality of rectangular regions 35 obtained by dividing the stripe region 32 in the x direction into the same size as the irradiation region 34 of the beam array. Further, in FIG. 16, in each rectangular region 35, writing is repeated under the same beam condition in the left half and the right half.

Therefore, when multiple writing is performed while shifting the beam array in the y direction by ¼ of the width size of the stripe region 32 and in the x direction by ⅛ of the width size, beam groups in blocks of the same symbol in 32 blocks A to D obtained by dividing the beam array into 8×4 blocks write the same region of the stripe region 32.

Therefore, the beam groups in the eight blocks of the symbol A among the plurality of blocks in the beam array write the same region of the stripe region 32 in the corresponding different passes or the same pass. In other words, the same pixel is irradiated with beams of corresponding arrangement positions in blocks of the same symbol (for example, A). For the correction coefficients of the eight beams with which the same pixel is irradiated, the weight coefficient setting unit 58 sets weight coefficients for beams such that correction coefficients are different in at least two passes among the passes. Alternatively, the weighting coefficients may be set for the respective beams such that correction coefficients are different between passes. Alternatively, the weighting coefficients may be set for the respective beams such that correction coefficients are different between blocks. Alternatively, the weighting coefficients may be set for the respective beams such that correction coefficients are different between beams.

As the irradiation time data generating step (S120), first, the rasterization processing unit 50 reads, for example, chip pattern data (writing data) for each stripe region 32 from the storage device 140, and performs a rasterization process. Specifically, the pattern density (pattern area density) is calculated for each pixel 36.

Next, the shot data generating unit 52 calculates, for each pixel 36, the dose D for irradiating the pixel 36. The dose D may be calculated, for example, as a value obtained by multiplying a preset base dose Dbase by a proximity effect correction dose coefficient Dp and a pattern area density p. As described above, the dose D is preferably obtained in proportion to the pattern area density calculated for each pixel 36. For the proximity effect correction dose coefficient Dp, the writing region (here, for example, the stripe region 32) is virtually divided into a plurality of proximity mesh regions (mesh regions for proximity effect correction calculation) in a mesh shape of a predetermined size. The size of the proximity mesh region is preferably set to about 1/10 of the range of influence of the proximity effect, which is, for example, about 1 μm. Then, the writing data is read from the storage device 140, and a pattern density p′ (pattern area density) of the pattern arranged in the proximity mesh region is calculated for each proximity mesh region.

Next, the proximity effect correction dose coefficient Dp for correcting the proximity effect is calculated for each proximity mesh region. Here, the size of the mesh region for which the proximity effect correction dose coefficient Dp is calculated is not necessarily the same as the size of the mesh region for which the pattern density p′ is calculated. The correction model of the proximity effect correction dose coefficient Dp and the calculation method thereof may be the same as the method used in the conventional single beam writing method.

Then, the shot data generating unit 52 calculates the beam irradiation time t of the electron beam for causing the calculated dose D to be incident on the pixel 36 for each pixel 36. The beam irradiation time t can be calculated by dividing the dose D by the current density J. As a result, a dose map (actually, a beam irradiation time map having the beam irradiation time data as an element) in which the beam irradiation time data (shot data) for each pixel 36 is defined is created.

When multiple writing is performed, a dose map (actually, a beam irradiation time map) is created for each writing process of each pass. In other words, a dose map (actually, a beam irradiation time map) is created for each stripe layer. The created beam irradiation time data is stored in the storage device 142.

As the beam irradiation time correcting step (S130), when multiple writing is performed on the same position of the target object 101 with a plurality of beams at different arrangement positions, two or more kinds of weighting coefficients being set for plurality of beams, among the multiple beams 20, the correcting unit 62 (an example of the beam irradiation time calculating unit) corrects the dose of the beam obtained in advance, using two or more kinds of weighting coefficients for the plurality of beams with which the position is written, for each beam of the plurality of beams with which the position is irradiated. As described above, the dose of each beam is obtained by multiplying the current amount and the beam irradiation time of each beam, and here, for example, the beam irradiation time of each beam is corrected. Therefore, in other words, when multiple writing is performed on the same pixel 36 (position) of the target object 101 as a writing target with a plurality of beams at different arrangement positions, for which two or more kinds of weighting coefficients are set, among the multiple beams 20, the correcting unit 62 (an example of the beam irradiation time calculating unit) calculates individual beam irradiation times t′ (i, j) of the beams corrected for each beam of a plurality of beams with which the pixel 36 is irradiated, using two or more kinds of weighting coefficients α (i, j) for the plurality of beams with which the pixel 36 is written and a current density J(i, j) of each beam of the plurality of beams. Specifically, the correcting unit 62 reads the correction coefficient K of the target beam and the beam irradiation time t(i, j) before correction from the storage device 142, and calculates the beam irradiation time t(i, j) after correction by multiplying the beam irradiation time t(i, j) before correction by the correction coefficient K for the beam. The created beam irradiation time data after correction is stored in the storage device 142 in order of shots.

In the above-described example, the configuration has been described in which the individual correction coefficient K is calculated first for each beam at each arrangement position and stored in the storage device 142, and then the correction coefficient K is read from the storage device 142 for correction of the beam irradiation time t(i, j) before correction. However, the configuration is not limited to the configuration described above. Without calculating the correction coefficient K in advance, the beam irradiation time t′ (i, j) after correction may be directly calculated using two or more kinds of weighting coefficients α (i, j) of the plurality of beams for writing the pixel 36 and the current density J(i, j) of each beam of the plurality of beams according to Formula (5) below.

$${t}^{′} ( i , j ) = t ( i , j ) \times \frac{n \times {J}_{0}}{1 / α ( i , j ) \times {Σ}_{{i}^{′} , {j}^{′}} α ( {i}^{′} , {j}^{′} ) \times J ( {i}^{′} , {j}^{′} )} \qquad ( 5 )$$

In addition, it is not always necessary to correct the beam irradiation time to correct the dose, and the current density (current amount) may be corrected. In this case, the correction may be performed by multiplying the base amount of the current density (current amount) or the base amount of the current density (current amount) by the correction coefficient K.

As the writing step (S140), the writing mechanism 150 writes a pattern on the target object 101 using the multiple beams 20 by performing multiple writing on each pixel 36 of the target object 101 with the plurality of beams with the respective corrected exposure intensities of the plurality of beams. As the writing step (S140), the writing mechanism 150 writes a pattern on the target object 101 using the multiple beams 20 by performing multiple writing on each pixel 36 of the target object 101 with the plurality of beams with the respective corrected exposure intensities of the plurality of beams. In other words, the writing mechanism 150 writes a pattern on the target object 101 using the multiple beams 20 by performing multiple writing on each pixel 36 of the target object 101 with a plurality of beams for the calculated individual beam irradiation times t′ (i, j).

As described above, the dose of each beam is obtained by multiplying the current amount of each beam by the beam irradiation time, and for each beam of the plurality of beams, the beam irradiation times of the beams are corrected using two or more kinds of weighting coefficients and the current amounts of the respective beams of the plurality of beams, and irradiation with each beam is performed for the corrected beam irradiation time.

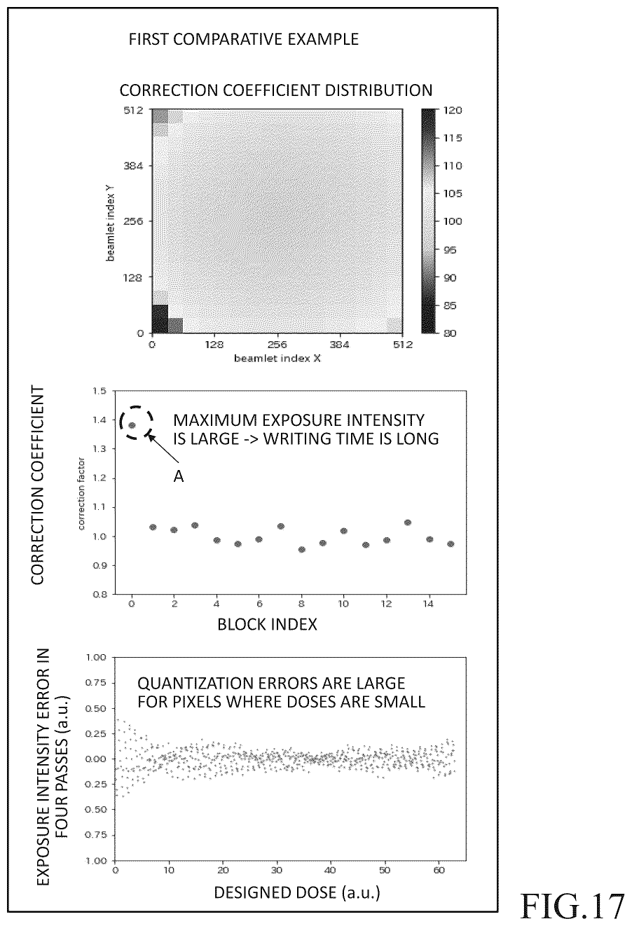

FIG. 17 is a diagram illustrating an example of a correction coefficient distribution and quantization errors in the first comparative example of the first embodiment.

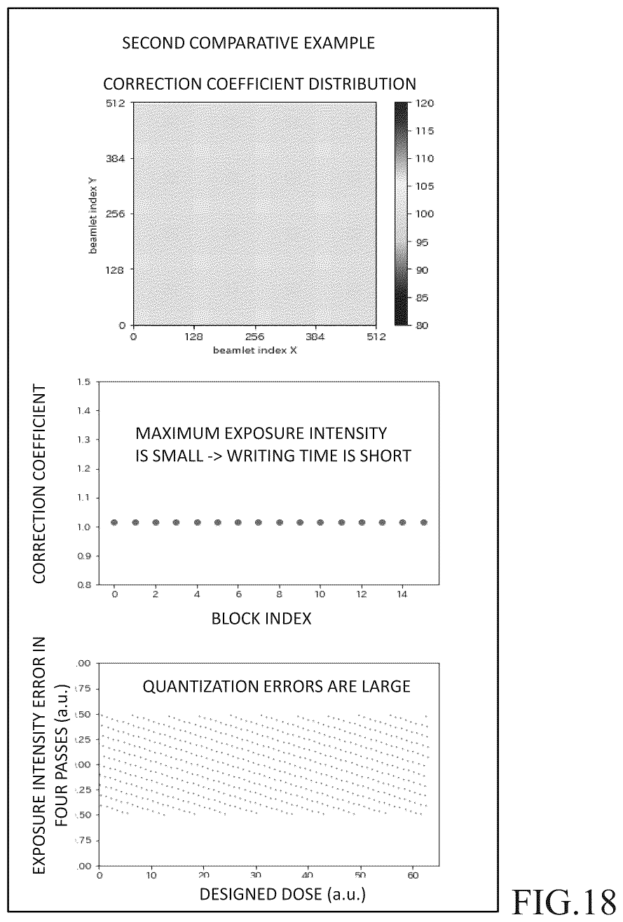

FIG. 18 is a diagram illustrating an example of a correction coefficient distribution and quantization errors in the second comparative example of the first embodiment.

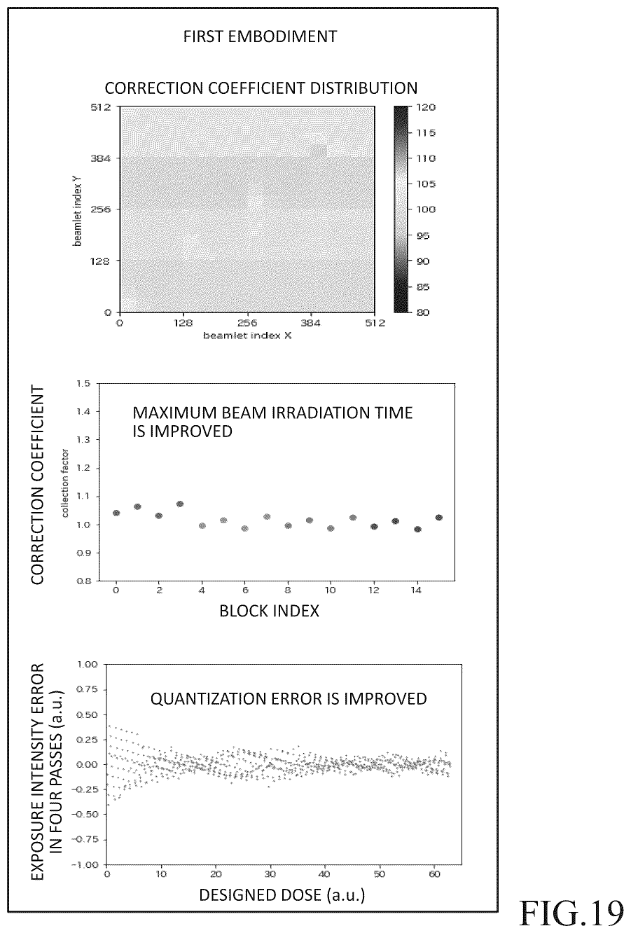

FIG. 19 is a diagram illustrating an example of a correction coefficient distribution and quantization errors in the first embodiment.

In FIGS. 17, 18, and 19, an example of an in-plane distribution diagram of correction coefficients is illustrated in the upper part. An example of a graph indicating the variation of the correction coefficients for the blocks is illustrated in the middle part. An example of the quantization errors for the designed doses is illustrated in the lower part.

In the first comparative example, as illustrated in the upper part of FIG. 17, the values of the correction coefficients of the peripheral beams having small current densities increase, and the beam irradiation times increase. The exposure intensities become uniform. However, as illustrated in part A of the middle part of FIG. 17, a singularly large correction coefficient may be generated. As a result, the beam irradiation time at the singular point is increased, and the shot cycle for all shots becomes long. As a result, the writing time becomes long, and the throughput is degraded. Furthermore, as illustrated in the lower diagram of FIG. 17, the quantization errors are large for pixels where doses are small. Therefore, the controllability of the pattern edge position tends to deteriorate.

In the second comparative example, averaging is performed as illustrated in the upper part of FIG. 18, and thus the values of the correction coefficients become substantially uniform. Therefore, the beam irradiation times are also uniform. In addition, as illustrated in the middle part of FIG. 18, the maximum beam irradiation times are shortened since the correction coefficients are substantially uniform. As a result, the writing time is shortened. However, as illustrated in the lower part of FIG. 18, the total quantization error increases since the beam irradiation times of the beams tend to be the same value, so that the quantization errors are accumulated in the same direction.

On the other hand, in the first embodiment, as illustrated in the upper and middle parts of FIG. 19, a singularly large value does not appear, and the correction coefficients can be prevented from being uniform. Therefore, the shot cycle can be suppressed from becoming long. Furthermore, as illustrated in the lower part of FIG. 19, the quantization errors of the beams can be averaged since the correction coefficients are not uniform. As a result, the magnitude of the total quantization error can be improved.

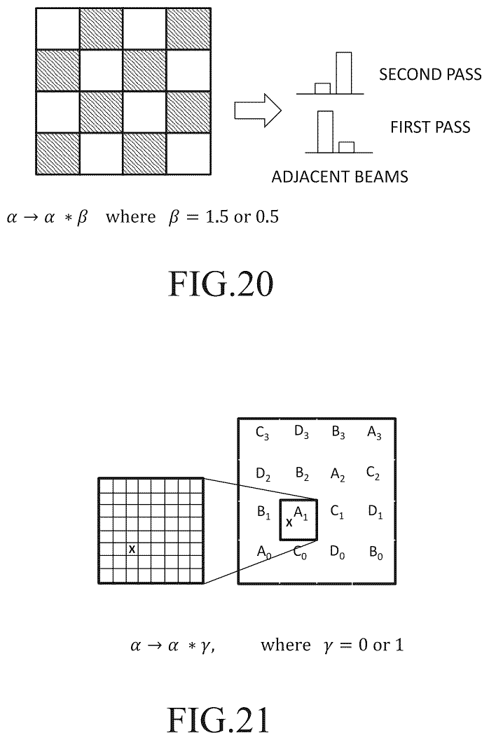

FIG. 20 is a diagram for describing a first modification of weighting coefficients in the first embodiment. In electron beam writing, so-called blurring due to Coulomb force is likely to occur. In order to reduce the influence of the Coulomb force, it is preferable to set a magnitude difference between doses of adjacent beams for irradiation at the same time. Therefore, as illustrated in FIG. 20, the magnitude of the dose of each beam of the multiple beams 20 may be set to form, for example, a checkered pattern. Therefore, the weighting coefficient α (i, j) is defined by a product of a plurality of independent weighting coefficient elements. In the example of FIG. 20, it is preferable to use, as the weighting coefficient α (i, j) set for each beam, a product of the weighting coefficient α (i, j) (first weighting coefficient) and the weighting coefficient β (i, j) (second weighting coefficient) for suppressing the Coulomb effect, which are independent of each other. In the case of the multiplicity 2, the weighting coefficient β (i, j) for suppressing the Coulomb effect is set to, for example, 1.5 for a first one of the beams adjacent to each other in the first pass and 0.5 for a second one of the beams. Then, for example, in the second pass, for example, 0.5 is set for the first one of the adjacent beams and 1.5 is set for the second one of the beams. As a result, the Coulomb effect can be reduced.

FIG. 21 is a diagram for describing a second modification of weighting coefficients in the first embodiment. Among the multiple beams 20, there may be a defect beam for which the dose cannot be controlled or which is always in the off state. Therefore, for these defect beams, the weighting coefficient is set to zero in order to set the corrected beam irradiation time to zero. Therefore, as illustrated in FIG. 21, it is preferable to use, as the weighting coefficient α (i, j) set for each beam, a product of the weighting coefficient α (i, j) (first weighting coefficient) and the weighting coefficient β (i, j) (second weighting coefficient) for defect beam determination, which are independent of each other. The weighting coefficient β (i, j) for defect beam determination may be set to 1 for the normal beam and to zero for the defect beam. Note that the always-on beam cannot be controlled and thus is excluded in the defect determination here. Note that the designed dose that would be required for beams where β (i, j)=0 may be allocated to beams of other passes.

As described above, according to the first embodiment, when multiple writing is performed on the target object 101 using the multiple beams 20, it is possible to reduce the quantization error while suppressing the throughput regardless of the presence or absence of a beam having a singular current density.

In addition, the functions of the processing described in the above-described embodiments may be executed by a computer. A program for causing the computer to execute the functions of the processing may be stored in, for example, a non-transitory tangible computer-readable storage medium such as a magnetic disk drive.

In addition, although description has not been provided for parts of the device configuration, the control method, and the like that are not directly necessary for the description of the present invention, a device configuration and a control method can be appropriately selected and used. For example, the description of the control unit configuration for controlling the writing apparatus 100 is provided, but it is obvious that a control unit configuration can be appropriately selected and used.

In the embodiment described above, the writing apparatus, the writing method, and the program using the charged particle beam have been described. However, the present invention can be applied to other writing apparatuses, writing methods, and programs that use, for example, a laser.

In addition, all multiple charged particle beam writing methods, multiple charged particle beam writing apparatuses and programs that can be obtained by appropriate design change of the embodiment described above by those skilled in the art and that include elements of the present invention are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multiple charged particle beam writing method comprising:
setting one of a plurality of weighting coefficients, for each beam of multiple charged particle beams according to arrangement positions of the multiple charged particle beams;
correcting, in a case where multiple writing is performed on a same position of a target object as a writing target with a plurality of beams at different arrangement positions, two or more kinds of weighting coefficients being set for the plurality of beams, among the multiple charged particle beams, a dose of a beam concerned obtained in advance, using the two or more kinds of weighting coefficients of the plurality of beams with which writing is performed on the position, for each beam of the plurality of beams with which the position is irradiated; and
writing a pattern on the target object using the multiple charged particle beams by performing multiple writing on a position of the target object with the plurality of beams with respective corrected doses of the plurality of beams for each position of the target object.

2. The method according to claim 1, wherein a dose of each beam of the plurality of beams is obtained by multiplying a current amount of a beam concerned by a beam irradiation time, and for the each beam of the plurality of beams, the beam irradiation time of the beam concerned is corrected using the two or more kinds of weighting coefficients and current amounts of the plurality of beams, and irradiation with each beam is performed using a corrected beam irradiation time.

3. The method according to claim 2, wherein a weighting coefficient set for the each beam is set independently of a current amount of a beam concerned.

4. The method according to claim 1, wherein a weighting coefficient is set for each beam of a plurality of beams to make a total value of doses of the plurality of beams with which each position of the target object is irradiated a designed value.

5. The method according to claim 1, wherein different weighting coefficients are set for the plurality of beams with which a same position of the target object is irradiated.

6. The method according to claim 1, wherein a product of a first weighting coefficient and a second weighting coefficient independent of each other is used as a weighting coefficient set for each beam.

7. A multiple charged particle beam writing apparatus comprising:
a setting circuit configured to set one of a plurality of weighting coefficients, for each beam of multiple charged particle beams according to arrangement positions of the multiple charged particle beams;
a correcting circuit configured to correct, in a case where multiple writing is performed on a same position of a target object as a writing target with a plurality of beams at different arrangement positions, two or more kinds of weighting coefficients being set for the plurality of beams, among the multiple charged particle beams, a dose of a beam concerned obtained in advance, using the two or more kinds of weighting coefficients of the plurality of beams with which writing is performed on the position for each beam of the plurality of beams with which the position is irradiated; and
a writing mechanism configured to write a pattern on the target object using the multiple charged particle beams by performing multiple writing on a position of the target object with the plurality of beams with respective corrected doses of the plurality of beams for each position of the target object.

8. A non-transitory computer-readable storage medium storing a program for causing a computer to execute processing, comprising:
setting one of a plurality of weighting coefficients, for each beam of multiple charged particle beams according to arrangement positions of the multiple charged particle beams;
storing the weighting coefficient set for each beam in a storage device; and
reading the weighting coefficient from the storage device, correcting, in a case where multiple writing is performed on a same position of a target object as a writing target with a plurality of beams at different arrangement positions, two or more kinds of weighting coefficients being set for the plurality of beams, among the multiple charged particle beams, a dose of a beam concerned obtained in advance, using the two or more kinds of weighting coefficients of the plurality of beams with which writing is performed on the position, for each beam of the plurality of beams with which the position is irradiated, and outputting a corrected dose.
